(19) United States
(12) Patent Application Publication
(10) Pub. No.: US 2012/0319907 A1
(43) Pub. Date: Dec. 20, 2012

(54) HOUSING OF ELECTRONIC DEVICE AND METHOD

(75) Inventors: Zhao-Yi WU, Shenzhen City (CN); Yong YAN, Shenzhen City (CN); Yong-Fa FAN, Shenzhen City (CN); Xue-Li ZHANG, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/247,013

(22) Filed: Sep. 28, 2011

(30) Foreign Application Priority Data
Jun. 16, 2011 (CN) 201110162367.X

(51) Int. Cl. H01Q 1/24; C23C 14/35; B05D 5/12

(52) U.S. Cl. 343/702; 427/123; 204/192.15

(57) ABSTRACT

The present invention discloses a housing for an electronic device and method for making the housing. The housing includes a base, an antenna radiator, and a decoration layer. The antenna is formed on the base by injection molding and is covered by the decoration layer. The antenna radiator is made of a primary layer, and plating plastic. The antenna is covered and protected by the decoration layer, thus, the housing can be used for a long period.

### BACKGROUND

1. Technical Field

The present disclosure relates to housings of electronic devices, especially to a housing having an antenna formed thereon and a method for making the housing.

2. Description of Related Art

Electronic devices, such as mobile phones, personal digital assistants (PDAs) and laptop computers are widely used. Most of these electronic devices have antenna modules for receiving and sending wireless signals. A typical antenna includes a thin metal radiator element mounted to a support member, and attached to a housing. However, the radiator element is usually exposed from the housing, and may be easily damaged and has a limited receiving effect. In addition, the radiator element and the support member occupy precious space.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary housing and the method for making the housing. Moreover, in the drawings like reference numerals designate corresponding parts throughout the several views. Wherever possible, the same reference numbers are used throughout the drawings to refer to the same or like elements of an embodiment.

FIG. 1 is a schematic view of an exemplary embodiment of a housing applied in an electronic device.

FIG. 2 is a cross-sectional view of a portion of the housing including antenna radiator taken along line II-II of FIG. 1.

FIG. 3 is a cross-sectional view of a portion of a molding machine of making the housing of FIG. 1.

FIG. 4 is similar to FIG. 3, but showing a base formed in a molding chamber.

FIG. 5 is similar to FIG. 4, but showing an antenna radiator formed on the base.

FIG. 6 is a schematic view of a PVD machine used in the present process.

### DETAILED DESCRIPTION

The disclosure is illustrated by way of example and not by way of limitation in the accompanying drawings. It should be noted that references to “an” or “one” embodiment in this disclosure are not necessarily to the same embodiment, and such references can include the meaning of “at least one” embodiment where the context permits.

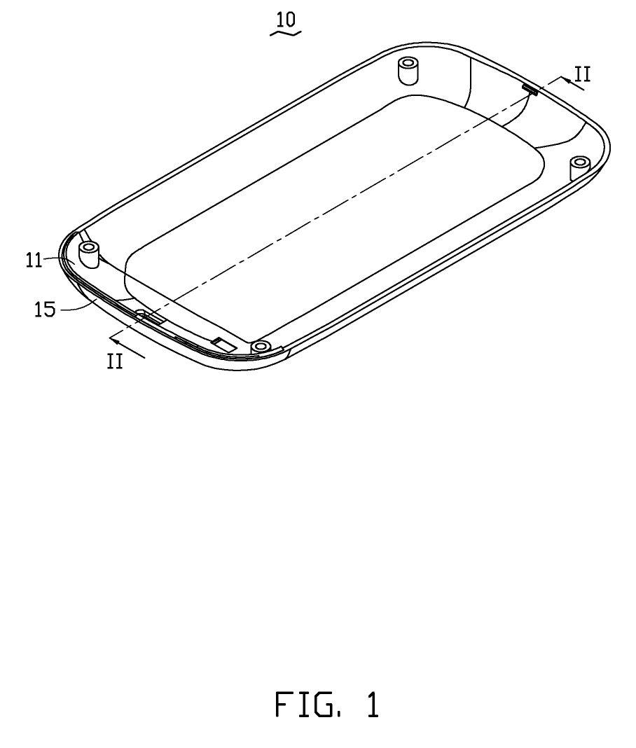

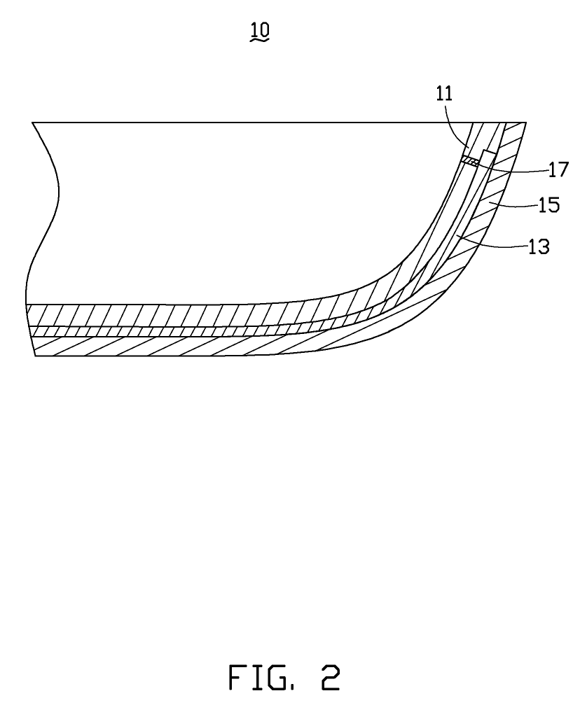

FIG. 1 shows an exemplary embodiment of a housing 10 for an electronic device where an antenna is needed, such as a mobile phone, or a PDA. Referring to FIG. 2, the housing 10 includes a base 11, an antenna radiator 13, a decoration layer 15, and a number of conductive contacts 17. The antenna radiator 13 is a three dimensional antenna and is formed in the base 11 and is buried by the decoration layer 15. The conductive contacts 17 are embedded in the housing 10 by insert-molding. One end of each conductive contact 17 is electrically connected to the antenna radiator 13, and the other end is exposed from the housing 10 so that the electronic device can receive signals from the antenna radiator 13 or transmit signals by the antenna radiator 13.

Referring to FIG. 2, the base 11 may be made of moldable plastic. The moldable plastic may be one or more non-plating plastics selected from a group consisting of polyethylene terephthalate (PET), and polymethyl methacrylate (PMMA).

The antenna radiator 13 includes a primary layer and a plating layer. The primary layer is made of plating plastic, which can be made of acrylonitrile butadiene styrene copolymer (ABC) or polypropylene (PP) or polycarbonate (PC) or polyurethane (TPU). The primary layer is formed on the base 11. The plating layer is formed on the primary layer. In this exemplary embodiment, the plating layer includes a copper layer, a nickel layer and a gold layer in that order. The copper layer is plated on the primary layer. The nickel layer is a transition layer and can increase the bonding force between the copper layer and the gold layer. The gold layer is plated on the nickel layer. Since the gold has high antioxidant properties, the gold layer can effectively protect the nickel layer and the copper layer.

The decoration layer 15 is formed on the base 11, and is buried on the antenna radiator 13. In this exemplary embodiment, the decoration is made of Silicon Nitrogen (Si—N) layer. The Si—N layer is formed on the base 11 by physical vapor deposition (PVD).

A method for making the housing 10 of the embodiment includes the following steps:

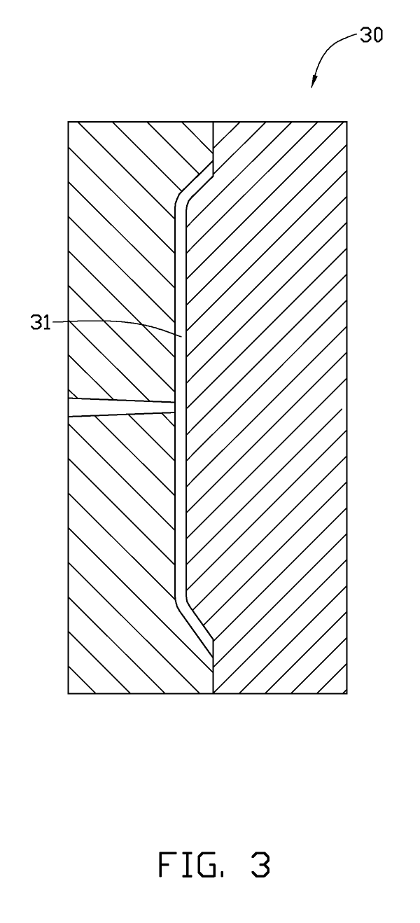

Referring to FIG. 3, an injection molding machine 30 is provided. The injection molding machine 30 is a multi-shot molding machine and includes a first molding chamber 31.

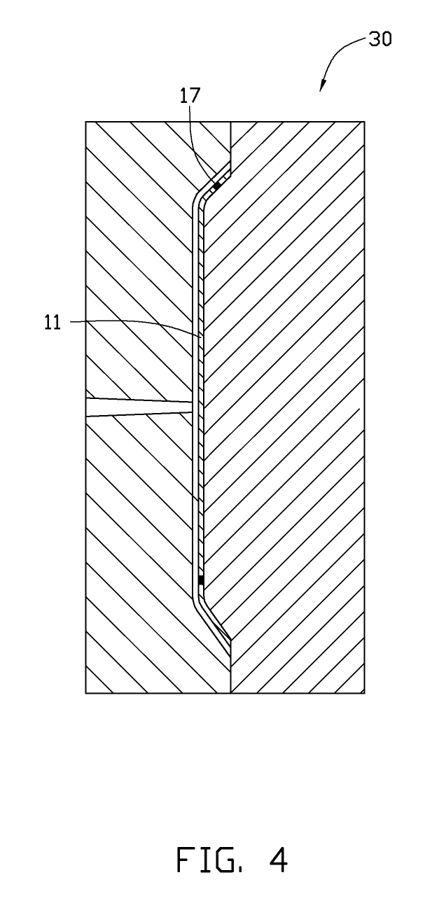

Referring to FIG. 4, the conductive contacts 17 are placed in the injection molding machine 30. Afterwards, non-plating molten plastic is fed into the molding chamber 31, and forms the base 11. The conductive contacts are embedded in the base 11. The base 11 is made of molded plastic, which may be one or more non-plating plastics selected from a group consisting of polyethylene terephthalate (PET), and polyethylene methacrylate (PMMA).

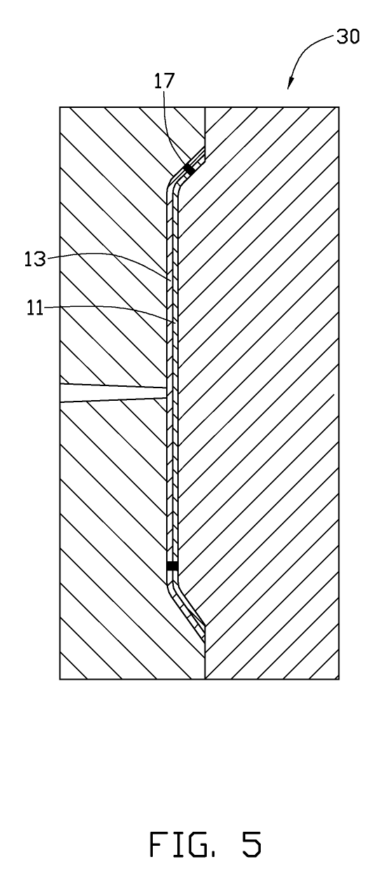

Referring to FIG. 5, the antenna radiator 13 includes a primary layer and a plating layer. The formation of the antenna radiator 13 is described in detail as follow. First, the plating plastic is injected into the molding chamber 31, forming the primary layer on the base 11. The plating plastic is selected from a group consisting of acrylonitrile butadiene styrene copolymer (ABC) or polypropylene (PP) or polycarbonate (PC) or polyurethane (TPU). Then, a copper layer, a nickel layer, and a gold layer are formed on the primary layer. The nickel layer is plated on the copper layer. The nickel layer is a transition layer, and the gold layer is plated on the nickel layer.

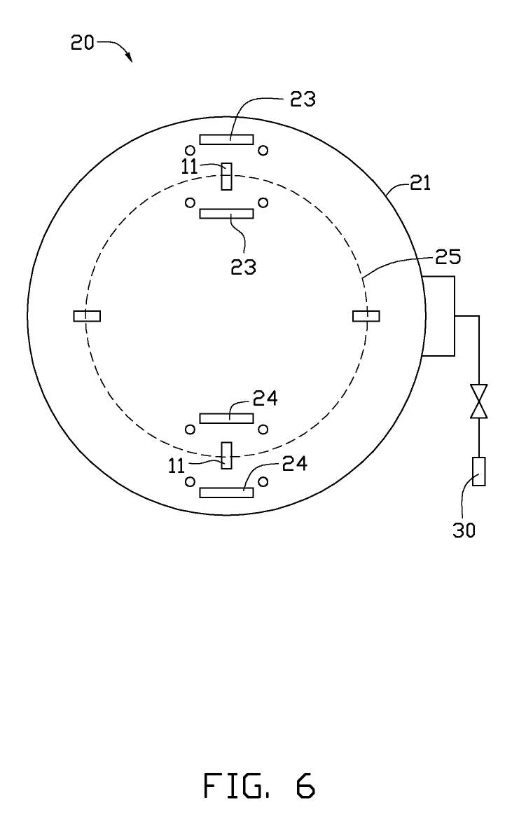

A vacuum sputtering process may be used to form the decoration layer 15 by a vacuum sputtering device 20. Referring to FIG. 6, the vacuum sputtering device 20 includes a vacuum chamber 21 and a vacuum pump 30 connected to the vacuum chamber 21. The vacuum pump 30 is used for evacuating the vacuum chamber 21. The vacuum chamber 21 has a pair of chromium targets 23, a pair of silicon targets 24 and a rotary rack (not shown) positioned therein. The rotary rack is rotated as it holds the substrate 11(circular path 25), and the substrate 11 revolves on its own axis while it is moved along the circular path 25.

Magnetron sputtering of the decoration layer 15 uses argon gas as sputtering gas. Argon gas has a flow rate of about 100 sccm to about 200 sccm. The temperature of magnetron sputtering is at about 100° C. to about 150° C., the power of the silicon target is in a range of about 2 kw to about 8 kw, a negative bias voltage of about −50 V to about −100 V is applied to the substrate and the duty cycle is about 30% to about 50%. The vacuum sputtering of the base takes about 90 minutes to about 180 minutes, the Si—N layer has a thickness at a range of about 0.5 μm to about 1 μm.

The antenna radiator 13 is sandwiched between the base 11 and the decoration layer 15 so that the antenna radiator 13 is protected from being damaged. In addition, the antenna radiator 13 can be directly attached to the housing 10, thus, the working efficiency is increased.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A housing comprising:
a base made of non-plating plastic;
an antenna radiator formed on the base, the antenna radiator including a primary layer made of plating plastic, and a plating layer;
a decoration layer formed on the antenna radiator; the antenna radiator sandwiched between the base and the decoration layer;
at least one conductive contact embedded in the base, one end of the at least one conductive contact electrically connected to the antenna radiator, and the other end of the at least one conductive contact exposed from the base.

2. The housing as claimed in claim 1, wherein the plating plastic is selected from the acrylonitrile butadiene styrene copolymer or polypropylene or polycarbonate or polyurethane.

3. The housing as claimed in claim 1, wherein the non-plating plastic includes polyethylene terephthalate, and polymethyl methacrylate.

4. The housing as claimed in claim 1, wherein the decoration layer is a non conductive Si—N layer.

5. The housing as claimed in claim 1, wherein the plating layer includes a copper layer, a nickel layer and an gold layer in that order.

6. The housing as claimed in claim 1, wherein the conductive contacts are embedded in the base.

7. A method for making a housing, comprising:
providing an injection molding machine defining a molding chamber;
placing at least one conductive contact into the molding chamber;
first injecting non-plating plastic into the molding chamber to form a base, the at least one conductive contact directly embedded in the base,
second injecting plating plastic on the base to form a primary layer;
plating a copper layer, a nickel layer and an gold layer in that order on the primary layer to form an antenna radiator;
forming a decoration layer, the decoration layer is a Si—N layer, forming Si—N layer by process of physical vapor deposition, the antenna radiator sandwiched between the decoration layer and the base.

8. The method for making a housing as claimed in claim 5, wherein magnetron sputtering the decoration layer uses argon gas as sputtering gas, argon gas has flow rates of 100 sccm to 200 sccm, the temperature of magnetron sputtering is at 100° C. to 150° C., the power of the silicon target is in a range of about 2 kw to about 8 kw, a negative bias voltage of −50 V to −100 V is applied to the substrate and the duty cycle is 30% to 50%, vacuum sputtering the base takes 90 min to 180 min, the Si−N layer has a thickness at a range of about 0.5 μm-1 μm.
